(19) United States
(12) Patent Application Publication
(10) Pub. No.: US 2015/0241525 A1
(43) Pub. Date: Aug. 27, 2015

(54) Dynamic Correction to Remove the Influence of Motor Coil Flux on Hall Sensor Measurement

(71) Applicant: Nikon Corporation, Tokyo (JP)

(72) Inventors: Pai-Hsueh Yang, Palo Alto, CA (US); Narutaka Yanagiya, Tokyo (JP); Takakuni Goto, Saitama (JP); Tsutomu Ogiwara, Saitama-ken (JP); Kazuhiro Hirano, Ageo (JP)

(21) Appl. No.: 14/565,835

(22) Filed: Dec. 10, 2014

Related U.S. Application Data
(60) Provisional application No. 61/914,137, filed on Dec. 10, 2013.

(51) Int. Cl. G01R 33/07; H02P 25/06; G03F 7/20; H02P 25/02

(52) U.S. Cl. CPC G01R 33/07; H02P 25/028; H02P 25/06; G03F 7/70716

(57) ABSTRACT

According to an aspect of the present invention, an apparatus includes a stage, at least a first coil, at least a first magnet, a plurality of Hall sensors, and a stage position estimation module. The first coil is included in a coil array that is a part of a coil arrangement. The first magnet is configured to cooperate with the first coil to form a motor that drives the stage. The dynamics model arrangement obtains a current command provided to the first coil and provides a first signal based on the current command. The Hall sensors are included in the coil arrangement, and are configured to measure a flux that includes a magnetic component and a coil component. The stage position estimation module is configured to obtain the flux and the first signal, and to process the flux and the first signal to estimate a position of the stage.

### CROSS REFERENCE TO RELATED APPLICATION

The present application claims benefit under 35 U.S.C. §119(e) of U.S. Provisional Patent Application No. 61/914,137, entitled “Dynamic Correction to Remove the Influence of Motor Coil Flux on Hall Sensor Measurement,” filed Dec. 10, 2013, which is incorporated herein by reference in its entirety for all purposes.

The present application is related to U.S. Provisional Patent Application No. 61/755,658 entitled “Hall Sensor Calibration and Servo for Planar Motor Stage,” filed Jan. 23, 2013, which is incorporated herein by reference in its entirety for all purposes.

### BACKGROUND OF THE INVENTION

1. Field of the Invention

The present invention relates generally to equipment used in semiconductor processing. More particularly, the present invention relates to reducing the effect of motor coil flux on a measurement of a position of a motor stage taken using a Hall sensor.

2. Description of the Related Art

The precise positioning of a wafer and a reticle during semiconductor processing is critical to the manufacturing of high density, semiconductor wafers. The accuracy with which a wafer and a reticle may be positioned is dependent upon the accuracy with which the positions of the wafer and the reticle, which are carried on stages, may be measured.

Hall sensors, or Hall Effect sensors, are often used in planar motor stage systems to measure the position of a motor stage. While Hall sensors are generally capable of accurately measuring the position of a motor stage, position measurement errors may arise due to coil fluxes associated with a planar motor stage that drives the motor stage. In other words, motor coil fluxes may interfere with measurements obtained using a Hall sensor. As a result of motor coil flux interference on Hall sensor measurements, the accurate determination of a position of a motor stage may be compromised.

### SUMMARY OF THE INVENTION

The present invention pertains to dynamically utilizing amplifier and sensor dynamics models to remove, or otherwise compensate for, the influence of motor coil flux on magnetic sensor signals, e.g., Hall sensor signals. Based on coil current commands provided to a motor coil, an amplifier and sensor dynamics model may effectively remove the influence of motor coil flux on magnetic sensor signals may be substantially minimized such that positions measurements estimated by a magnetic sensor may be improved, particularly at relatively high frequencies.

According to one aspect of the present invention, an apparatus includes a stage, at least a first coil, at least a first magnet, at least a first plurality of magnetic sensors, and a stage position estimation module. The at least first coil is included in a coil array, the coil array being a part of a coil arrangement, and the first magnet is configured to cooperate with the first coil to form a motor arranged to drive the stage. The dynamics model arrangement is configured to obtain a coil current command provided to the at least first coil and to provide a first signal based on the coil current command. The first plurality of magnetic sensors is included in the coil arrangement, and the first plurality of magnetic sensors is configured to measure a flux, wherein the flux includes a magnetic component associated with the at least first magnet and a coil component associated with the at least first coil. The stage position estimation module is configured to obtain the flux and the first signal, and is further configured to process the flux and the first signal to estimate a position of the stage. In one embodiment, the first plurality of magnetic sensors are a first plurality of Hall Effect or Hall sensors.

According to another aspect of the present invention, an apparatus includes a stage, a first coil, a second coil, at least a first magnet, a first dynamics model arrangement, a second dynamics model arrangement, and a first magnetic sensor. The first coil and the second coil are included in a coil array that is a part of a coil arrangement. The first magnet is configured to cooperate with the coil array to form a planar motor arranged to drive the stage. The first dynamics model arrangement is configured to obtain a first coil current command provided to the first coil and to provide a first signal based on the first coil current command. The second dynamics model arrangement is configured to obtain a second coil current command provided to the second coil and to provide a second signal based on the second coil current command. The first magnetic sensor is included in the coil arrangement, and is configured to measure a flux. The flux includes a magnetic component associated with the at least first magnet and a first coil component associated with the at first coil and a second coil component associated with the second coil, wherein a calibrated magnetic sensor signal is obtained by compensating for the first coil component and the second coil component in the flux. In one embodiment, the magnetic sensor may be a Hall Effect or Hall sensor.

### BRIEF DESCRIPTION OF THE DRAWINGS

The invention will be readily understood by the following detailed description in conjunction with the accompanying drawings, in which:

FIG. 1 is a diagrammatic representation of an arrangement in which Hall sensors are arranged to measure magnetic flux associated with a planar motor used to drive a motor stage such that a position of the motor stage may be determined in accordance with an embodiment of the present invention.

FIG. 2 is a diagrammatic representation of a system which uses motor coil current commands to compensate for the influence of motor coil flux on a Hall sensor position measurement in accordance with an embodiment of the present invention.

FIG. 3 is a diagrammatic representation of control arrangement in accordance with an embodiment of the present invention.

FIG. 4 is a process flow diagram which illustrates a method of estimating at least one stage position using signals obtained from a plurality of Hall sensors in accordance with an embodiment.

FIG. 5 is a diagrammatic representation of a stage assembly with one suitable arrangement of Hall sensors, e.g., one suitable Hall sensor system, in accordance with an embodiment of the present invention.

FIG. 6 is a diagrammatic representation of a checkerboard array of motor coils suitable for use in a planar motor in accordance with an embodiment of the present invention.

FIG. 7A is diagrammatic representation of another suitable Hall sensor configuration in accordance with an embodiment of the present invention.

FIG. 7B is diagrammatic representation of still another suitable Hall sensor configuration in accordance with an embodiment of the present invention.

FIG. 8 is a diagrammatic representation of a system which obtains coil current command signals and a measured Hall sensor signal for a particular Hall sensor, and obtains a calibrated signal for the particular Hall sensor in accordance with an embodiment of the present invention.

FIG. 9 is a diagrammatic representation of a portion of a planar motor in accordance with an embodiment of the present invention.

FIG. 10 is a diagrammatic representation of a photolithography apparatus in accordance with an embodiment of the present invention.

FIG. 11 is a process flow diagram which illustrates the steps associated with fabricating a semiconductor device in accordance with an embodiment of the present invention.

FIG. 12 is a process flow diagram which illustrates the steps associated with processing a wafer, i.e., step 1113 of FIG. 11, in accordance with an embodiment of the present invention.

### DETAILED DESCRIPTION OF THE INVENTION

Example embodiments of the present invention are discussed below with reference to the various figures. However, those skilled in the art will readily appreciate that the detailed description given herein with respect to these figures is for explanatory purposes, as the invention extends beyond these embodiments.

Stage positions are often measured using magnetic sensors such as Hall Effect sensors or, more generally, Hall sensors. As will be appreciated by those skilled in the art, a Hall sensor is a transducer arranged to output a voltage. The outputted voltage is generally directly proportional to the size of an electric current and the strength of a magnetic field.

Hall Effect sensors are generally noncontact sensors which output a signal proportional to input magnetic field strength. The Hall Effect refers to voltage generated when a current carrying conductor or semiconductor is exposed to magnetic flux in a direction perpendicular to the direction of the current. A voltage, i.e., the Hall voltage, is generated in a direction perpendicular to both the current and the applied magnetic field. In order to use a Hall Effect sensor as a displacement sensor, the sensor is typically matched with a moving permanent magnet. This magnet may be applied to the target. For a planar motor stage, its magnet array may be used as the measurement target of Hall Effect sensors.

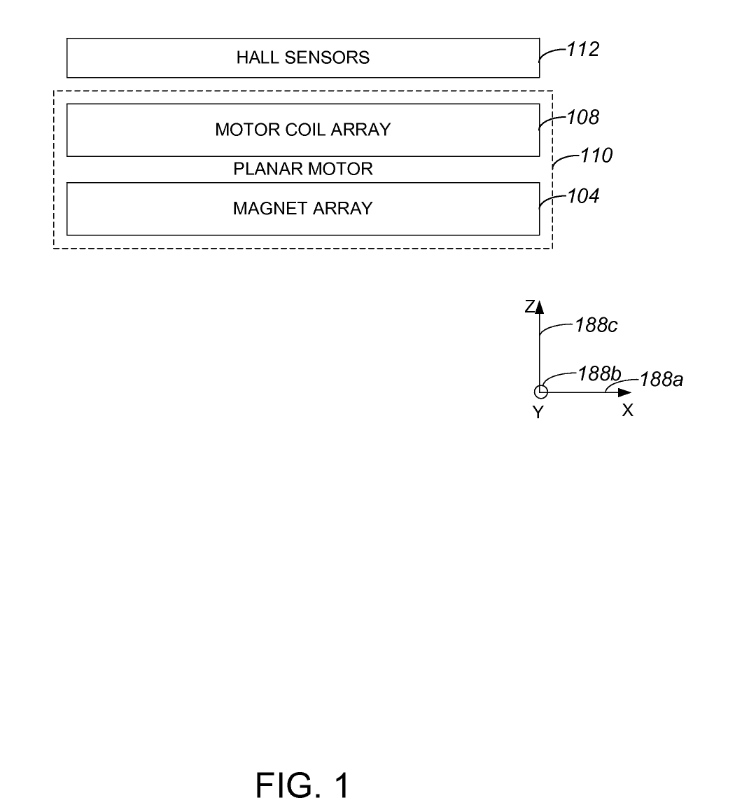

The voltage output of a Hall sensor may be used to estimate a position of a stage. A Hall sensor may be located substantially within a motor coil array of a planar motor used to drive a stage. For example, a Hall sensor may essentially be mounted on, or at a distance from, a planar motor coil unit of a planar motor used to drive a stage. FIG. 1 is a diagrammatic representation of an arrangement in which Hall sensors are arranged to measure magnetic flux associated with a planar motor used to drive a motor stage such that a position of the motor stage may be determined in accordance with an embodiment of the present invention. A planar motor 110 includes a magnet array 104, or an array of magnets, and a motor coil array 108, or an array of coils. A motor stage (not shown) may be driven by planar motor 110 along an x-axis 188a and/or a y-axis 188b when motor coil array 108 is energized, i.e., when electrical current is provided to motor coil array 108. A plurality of Hall sensors 112 may be mounted on, or positioned at a distance from, motor coil array 108 relative to a z-axis 188c. In other words, Hall sensors 112 may be placed on, placed over, and/or placed under coils of coil array 108, i.e., Hall sensors 112 may be placed in or on substantially any available space of coil array 108. It should be appreciated that Hall sensors are generally used to measure magnet position, or positions of magnets in magnet array 104, relative to coil array 108.

Measurements provided by the Hall sensor, e.g., the voltage that is outputted by the Hall sensor may be used to measure the magnetic flux of magnets of a planar motor. A voltage that is output by a Hall sensor is essentially provided in response to a magnetic field. When stage positions are estimated or otherwise measured using Hall sensors, the accuracy of measurements may be adversely affected by a motor coil flux, or a flux generated by the motor coils of the planar motor when the motor coils are energized. For example, when there is a relatively high motor coil flux, position measurements estimated by or otherwise obtained by a Hall sensor may be compromised. As will be understood by those skilled in the art, a magnetic field from an energized coil is typically proportional to an actual current provided to the coil. In addition, coils that substantially surround an energized coil may also generate magnetic flux due to the influence of mutual induction. Such coil mutual induction generally causes Hall sensors positioned near an energized coil to respond differently from a pure amplifier dynamics model. As such, measurements of a frequency response of substantially all Hall sensor within a vicinity of, e.g., within a particular range of, the energized coil. In other words, the interference on a Hall sensor due to flux generated from a coil nearest to the Hall sensor is different from the interference on the Hall sensor due to flux generated from other nearby coils. As a result, current commands of coils around a Hall sensor may be accounted for in a compensation formula for the Hall sensor. For a Hall sensor positioned substantially under an energized coil or substantially over an energized coil, a combined model of amplifier and sensor dynamics may be directly measured.

In one embodiment, at least one Hall sensor may be included in a coil arrangement that includes one or more planar coil units of a planar stage apparatus, e.g., included in a coil arrangement that also includes a coil array. A Hall sensor may be mounted to or at a distance from one or more planar coil units of a planar stage apparatus to measure magnetic flux or, more generally, to provide signals which may be used to estimate a stage position. To effectively compensate for the effects of a motor coil flux which is substantially generated by the planar coil units and detected by a Hall sensor, circuitry or components may be provided in a control system to use a current command to effectively negate the effects of the motor coil flux. A coil unit array may generally cooperate with an array of magnets to function as a planar motor. In order for the influence of flux associated with, e.g., generated by, a motor coil to be substantially reduced, amplifier and sensor dynamics models may be arranged to effectively remove effects of motor coil fluxes such that hall sensors mounted on one or more planar motor coil units may be used to measure magnetic flux of magnetic arrays substantially without being affected by motor coil fluxes.

Hall sensors mounted on or positioned at a distance from the planar motor coil units of planar motors may be used to measure the magnetic flux of magnet arrays. Stage positions may be estimated, as for example using any suitable stage position estimation formula, using the measurements of magnet flux provided by Hall sensors. However, in addition to measuring the magnetic flux of magnet arrays, Hall sensors also pick up magnetic flux from energized coils of planar motors, which contributes significant stage position estimation errors. Because the actual coil current is delivered by motor amplifiers, which have a substantially finite bandwidth and system delay, actual coil current differs from the current command in the control software. Further, signal processing components, as for example electronics, of Hall sensors also introduce time delay and dynamics changes to the sensor data, e.g., data provided by Hall sensors, used in the position estimation. To accommodate dynamics transitions of current amplifiers and sensor electronics, relatively detailed dynamics models for current amplifiers and Hall sensors are may be applied to accurately compensate for any effects of motor coil flux on Hall sensors. As will be appreciated by those skilled in the art, such detailed dynamics models may be obtained through calibration processes. For example, to generate a model for Hall sensor dynamics, coils may be energized at different frequencies such that a transfer function may be obtained.

As previously mentioned, Hall sensors may be located within a motor coil array assembly, and may generally be used to measure the magnetic flux of a motor magnet array. From at least two Hall sensors, related positions of the magnet array and the motor coil array assembly may be estimated, as for example in an x-direction and a z-direction, or in a y-direction and a z-direction. Position estimation errors may result from magnetic flux generated by current in motor coils, as the Hall sensors generally pick up the magnetic flux generated by the current in motor coils in addition to the magnetic flux of a motor magnet array. By substantially removing the magnetic flux effect of coil current on Hall sensor readings, the Hall sensor signals may account substantially only for the magnetic flux of the motor magnet array. Thus, the accuracy of position estimates for a motor stage determined using Hall sensor readings may be improved.

As will be appreciated by those skilled in the art, motor current commands may be generated by a stage controller and provided to amplifiers, which generate actual currents to be provided to coils. The amplifiers are dynamic systems, and the Hall sensor data acquisition and conditioning units are also generally dynamic systems. Without directly measuring actual coil currents, information pertaining to actual coil currents may be obtained from coil current commands and an amplifier dynamics model. Actual Hall sensor signals may be slightly different after processing by sensor conditioning and data acquisition units. As a result, the correction of Hall sensor signals to remove a magnetic flux effect from coil currents takes amplifier dynamics and Hall sensor data acquisition dynamics into account.

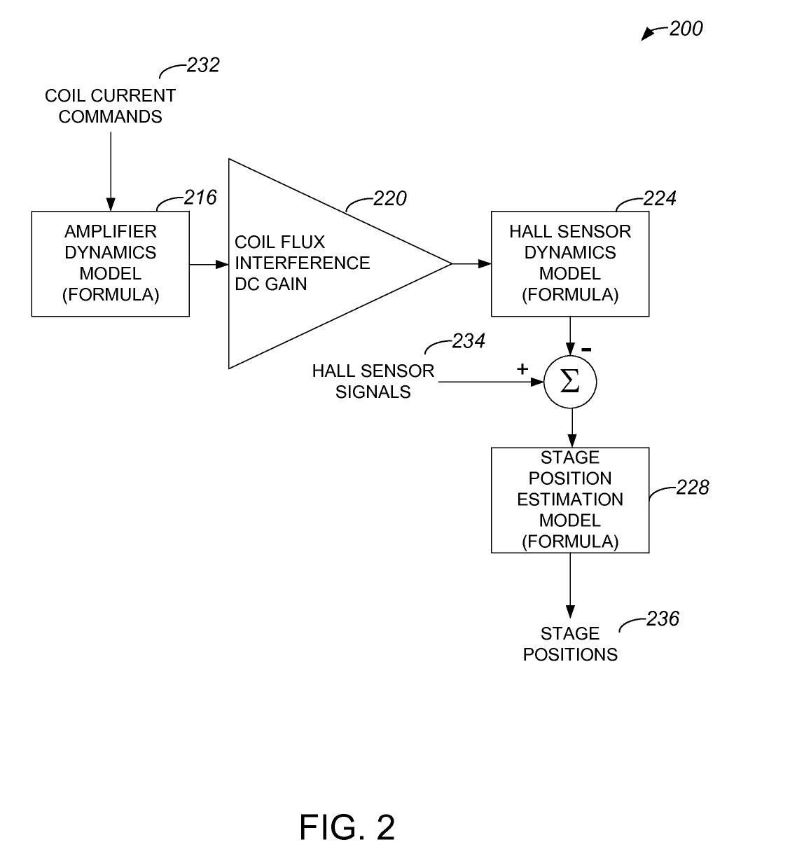

FIG. 2 is a diagrammatic representation of a system which uses motor coil current commands to compensate for the influence of motor coil flux on a Hall sensor position measurement in an overall stage system in accordance with an embodiment of the present invention. A system 232 which is arranged to obtain stage positions using information based on coil current commands includes an amplifier dynamics model 216, a coil flux interference DC gain 220, a hall sensor dynamics model 224, and a stage position estimation model 228.

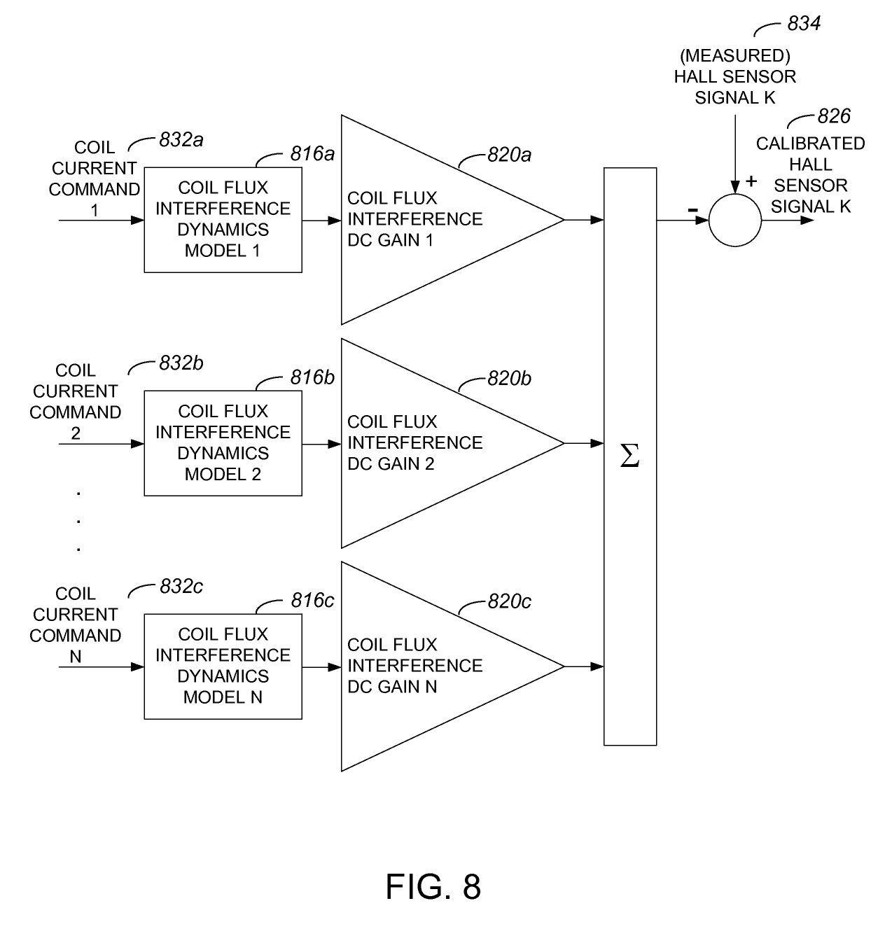

Motor coil current commands 232, which are generally current commands to at least one coil of a planar motor (not shown) arranged to drive a stage (not shown). Coil current commands 232 are provided to amplifier dynamics model 216. Amplifier dynamics model 216 may be generated by curve-fitting a measured amplifier input/output frequency response. As will be appreciated by those skilled in the art, amplifier dynamics model 216, Hall sensor dynamics model 224, and stage position estimation model 228 may vary widely. Further, different coils of a coil array may have different current commands and/or be associated with different amplifier dynamics models and different Hall sensor dynamics model 224, as will be discussed below with respect to FIG. 8.

Output from amplifier dynamics model 216 may be used to determine a motor coil flux interference gain 220, e.g., a DC gain. Such a DC gain is generally a DC correction gain, and may be determined during a calibration process by providing, e.g., injecting, current to individual coils near a Hall sensor that is being calibrated. A DC correction gain “g” associated with a Hall sensor “k” and a coil “j” may be expressed as follows:

$${g}_{k , j} = \frac{Δ {v}_{k , j}}{Δ Ij}$$

where Δv_{k,j} is a DC voltage deviation of Hall sensor due to a current command ΔIⱼ of coil “j”.

The DC gain may be provided to Hall sensor dynamics model 224, which may be generated by curve-fitting measured sensor input/output frequency responses. Hall sensor dynamics model 224 provides an output that effectively compensates for motor coil flux associated with a planar motor (not shown). The output of the Hall sensor dynamics model 224 may be provided, in conjunction with at least one Hall sensor signal 234 or measured flux, to stage position estimation model 228. In one embodiment, stage position estimation model 228 is provided with a relatively accurate measurement of magnetic flux associated with a planar motor 228 after motor coil flux is substantially eliminated. Stage position estimation model 228 is arranged to use measurements of magnetic flux to determine stage positions 236. In one embodiment, stage position estimation model 228 may essentially use a difference between Hall sensor signal 234 and the output of Hall sensor dynamics model 224, which is the estimated coil flux induced Hall sensor signal, to estimate stage positions 236. The difference between Hall sensor signal 234 and the output of Hall sensor dynamics model 224 may be considered to be a calibrated Hall sensor signal.

Generally, without any correction or compensation, position-dependent planar motor currents may significantly interfere with the accurate operation of Hall sensors. Interference with Hall sensors often causes stage plant and closed-loop responses to change significantly with stage position. Without sensor correction or compensation for motor coil flux, stage performance may be compromised. DC gain correction of Hall sensor signals with coil current commands may, in one embodiment, lead to more consistent plant and closed-loop responses at lower frequencies, e.g., below approximately 25 Hertz (Hz). Dynamic correction based on more complete amplifier and Hall sensor dynamics models effectively recover the measurement accuracy associated with measurements of a Hall sensor in a broader frequency area.

Amplifier and Hall sensor dynamics models may be substantially created through a dynamic calibration process. In other words, coil flux influence on measurements taken using a Hall sensor may be dynamically calibrated. Hall sensors generally respond to energized coils, or coil currents, differently based on any number of different factors. Such factors include, but are not limited to including, the relative positions of a coil and a sensor. A dynamic calibration process may include fitting a measured frequency response with a parametric transfer function by energizing a coil, e.g., using a swept sine analysis. The parametric transfer function may be used for dynamic correction.

The influence of flux from coils within a particular vicinity or area may be substantially removed from measurements taken from a Hall sensor within the particular vicinity dynamically. That is, more than one coil may generate coil flux artifacts which are measured by a Hall sensor. The process of removing the influence of flux from coils within a particular vicinity or area generally provides dynamic correction of at least one coil flux artifact for a Hall sensor within the particular vicinity. FIG. 8 is a diagrammatic representation of a system which obtains coil current command signals and a measured Hall sensor signal for a particular Hall sensor, and obtains a calibrated signal for the particular Hall sensor in accordance with an embodiment of the present invention. With respect to a Hall sensor “K”, coil current commands 832a-c may be provided to “N” coils which are located near Hall sensor “K” and generate either a magnetic field due to energized coil current or a magnetic field due to mutual induction that have an influence on measurements taken by Hall sensor “K”.

Each coil current command 832a-c is obtained by its corresponding coil flux interference dynamics model 816a-c, and the outputs of coil flux interference dynamics model are subject to coil flux interference gains 820a-c. Coil flux interference dynamics models 816a-c are, in one embodiment, combined modes of amplifier and Hall sensor dynamics. The overall signals associated with coil current commands 832a-c, which are generated after gains 820a-c are applied, are effectively summed together, and effectively subtracted from a measured signal 834 from Hall sensor signal “K” 834 to generated a calibrated Hall sensor signal “K” 826, or an effective signal associated with Hall sensor “K” after a coil flux influence has been accounted for. Calibrated Hall sensor signal “K” may be used, e.g., by a stage position estimation model (not shown), to estimate a position of a stage.

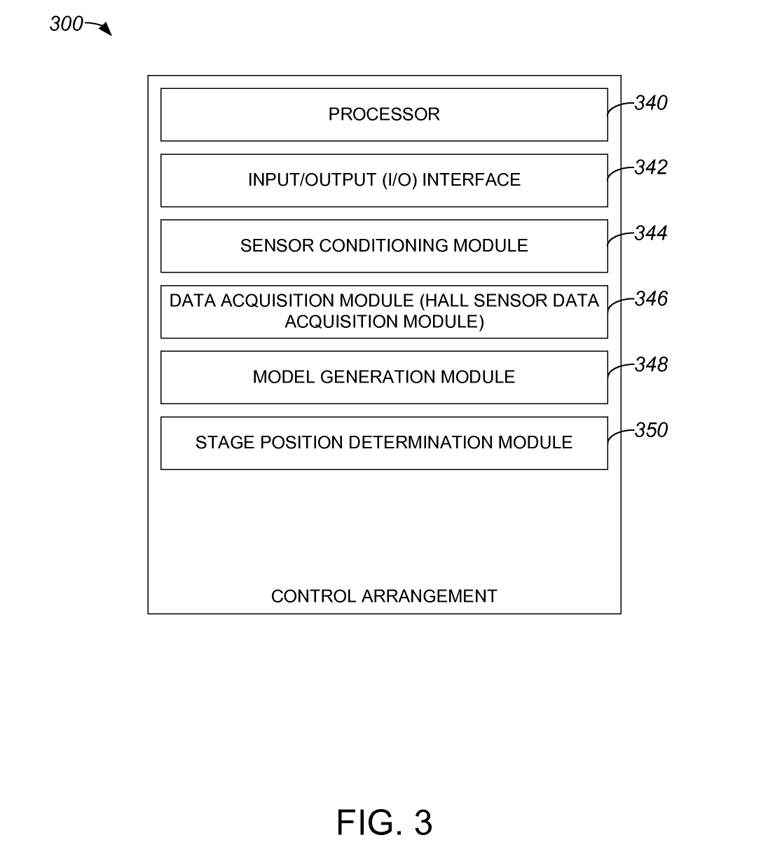

With reference to FIG. 3, a control arrangement configured to determine a stage position using measurements obtained from a Hall sensor arrangement will be described in accordance with an embodiment of the present invention. A control arrangement 300 may be included as a part of an overall controller of an exposure apparatus that includes a planar motor which drives a stage. Control arrangement 300 includes a processor 340, an input/output (I/O) interface 342, a sensor conditioning module 344, a data acquisition module 346, a model generation module 348, and a stage position determination module 350. Processor 340 is arranged to execute software logic which may be included in sensor conditioning module 344, data acquisition module 346, model generation module 348, and stage position determination module 350.

I/O interface 342 is arranged to obtain information, e.g., information relating to signals, including, but not limited to including, information associated with coil current commands and information associated with Hall sensors. Sensor conditioning module 344 is arranged to conditioning sensors such as Hall sensors, while data acquisition module 346 is configured to acquire data or information relating to Hall sensors. Model generation module 348 is arranged to generate models, e.g., an amplifier dynamics model and a Hall sensor dynamics model. Stage position determination module 350 is configured to use information associated with coil current command signals and Hall sensor signals to obtain a stage position. In one embodiment, stage position determination module 350 may effectively use information obtained from Hall sensors, e.g., magnetic flux measurements associated with a planar motor, substantially after motor coil flux is accounted for, to obtain a stage position.

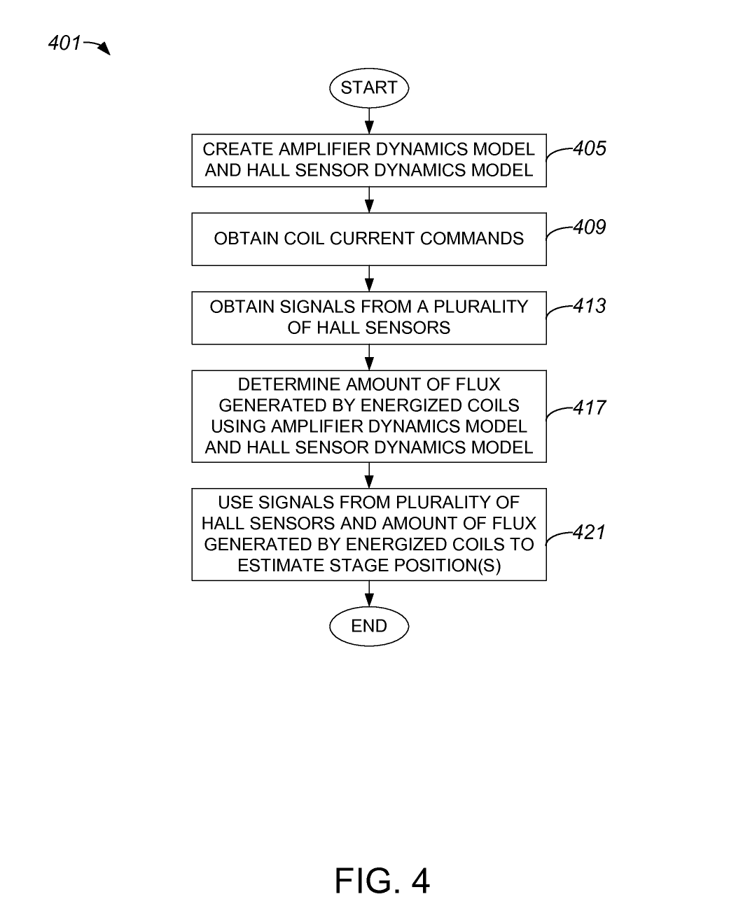

FIG. 4 is a process flow diagram which illustrates a method of estimating at least one stage position using signals obtained from a plurality of Hall sensors in accordance with an embodiment. A process 401 of estimating at least one stage position for a stage that is driven by a planar motor arrangement which includes Hall sensors begins at step 405 in which an amplifier dynamics model and a Hall sensor dynamics model are created. Creating dynamics models may include, but is not limited to including, obtaining transfer functions for both an amplifier that amplifies a current command and at least one Hall sensor which is configured to measure magnetic flux associated with a planar motor which drives a stage.

In step 409, coil current commands, or current commands used to determine an amount of current to provide to coils of a planar motor, are obtained. After coil current commands are obtained, signals may be obtained from a plurality of Hall sensors in step 413. An amount of flux generated by energized coils of the planar motor is determined in step 417 using the amplifier dynamics model and the Hall sensor dynamics model. In other words, an amount of motor coil flux generated when motor coils are energized is determined.

Once an amount of flux generated by energized coils is determined, process flow moves to step 421 in which signals from the plurality of Hall sensors and the amount of flux generated by energized coils are used to estimate at least one stage position. In one embodiment, the amount of flux generated by the energized coils may effectively be subtracted from the amount of flux associated with the signals from the plurality of Hall sensors. Upon estimating stage positions, the process of estimating at least one stage position is completed.

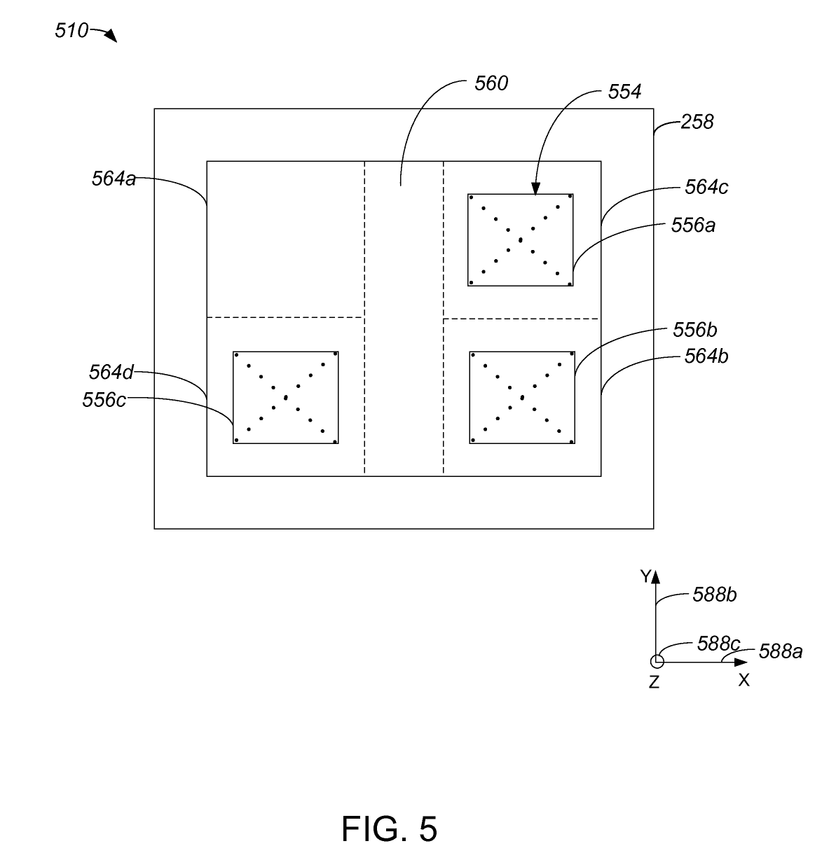

The orientation of Hall sensor groups, as well as the number of Hall sensors in each group, included in a coil arrangement that also includes a coil array may vary widely. Examples of suitable Hall sensor groups are described in U.S. Provisional Patent Application No. 61/755,658 entitled “Hall Sensor Calibration and Servo for Planar Motor Stage,” filed Jan. 23, 2013, which is incorporated by reference. FIG. 5 is a diagrammatic representation of a stage assembly with one suitable arrangement of Hall sensors, e.g., one suitable Hall sensor system, in accordance with an embodiment of the present invention. It should be appreciated that while the Hall sensor system shown in FIG. 5 is one example of a suitable Hall sensor system, suitable Hall sensor systems may vary widely depending upon the requirements of an overall exposure apparatus that includes a stage assembly. A hall sensor system 554 includes approximately three separate and spaced apart Hall sensor groups 556a, 556b, 556c that may be secured or otherwise coupled to a base 258. In the described embodiment, each Hall sensor group 256a, 256b, 256c may be designed or otherwise configured to monitor the position and/or movement of a stage 560 along two axes. For example, Hall sensor system 554 may include first Hall sensor group 256a that monitors the position and/or movement of stage 560 along a y-axis 588b and a z-axis 588c, second Hall sensor group 556b that monitors the position and/or movement of stage 560 along an x-axis 588a and z-axis 588c, and third Hall sensor group 556c that monitors the position and/or movement of stage 560 along y-axis 588b and z-axis 588c. In the described embodiment, the signals from Hall sensor groups 256a, 256b, 256c may be used to monitor the position and/or movement of stage 560 along and/or about the x-axis 588a, y-axis 588b, and z-axis 588c.

As shown in FIG. 5, at the current position of stage 560 relative to base 258, first Hall sensor group 556a is positioned substantially directly under a first Y magnet array 564c, third Hall sensor group 556c is positioned substantially directly under a second Y magnet array 564d, and second Hall sensor group 556b is positioned substantially directly under a second X magnet array 564b It should be appreciated that at the current position of stage 560 relative to base 258, as shown, there is no Hall sensor under a first X magnet array 564a. While Hall sensor groups 556a, 556b, 556c have been described as being under magnet arrays 564c, 564b, 564d, respectively, Hall sensor groups 556a, 556b, 556c may instead be located over magnet arrays 564c, 564b, 564d, respectively. In other words, Hall sensor groups 556a, 556b, 556c are generally located at a distance from magnet arrays 564c, 564b, 564d, respectively, along z-axis 588c.

It should be appreciated that the measurement range of Hall sensor system 554 may be relatively small. The measurement range of Hall sensor system 554 may be improved, in one embodiment, with the addition of additional Hall sensor groups along base 558.

As mentioned above, the orientation and number of Hall sensors in Hall sensor groups may vary widely. By way of example, the number of Hall sensors in Hall sensor groups 556a, 556b, 556c of FIG. 5, as well as the orientation of the Hall sensors in Hall sensor groups 556a, 556b, 556c may vary widely. In the embodiment shown in FIG. 5, each Hall sensor groups 556a, 556b, 556c may include seventeen, individual Hall sensors that are spaced approximately ninety degrees apart along x-axis 588a and along y-axis 588b. The approximately ninety degrees at which Hall sensors are spaced apart is typically in relation to motor commutation, and may depend on the design of an overall magnet array which includes magnet arrays 564b, 564c, 564d. The output from each Hall sensor may be a sinusoidal function of either a position relative to y-axis 588b or a position relative to x-axis 588a.

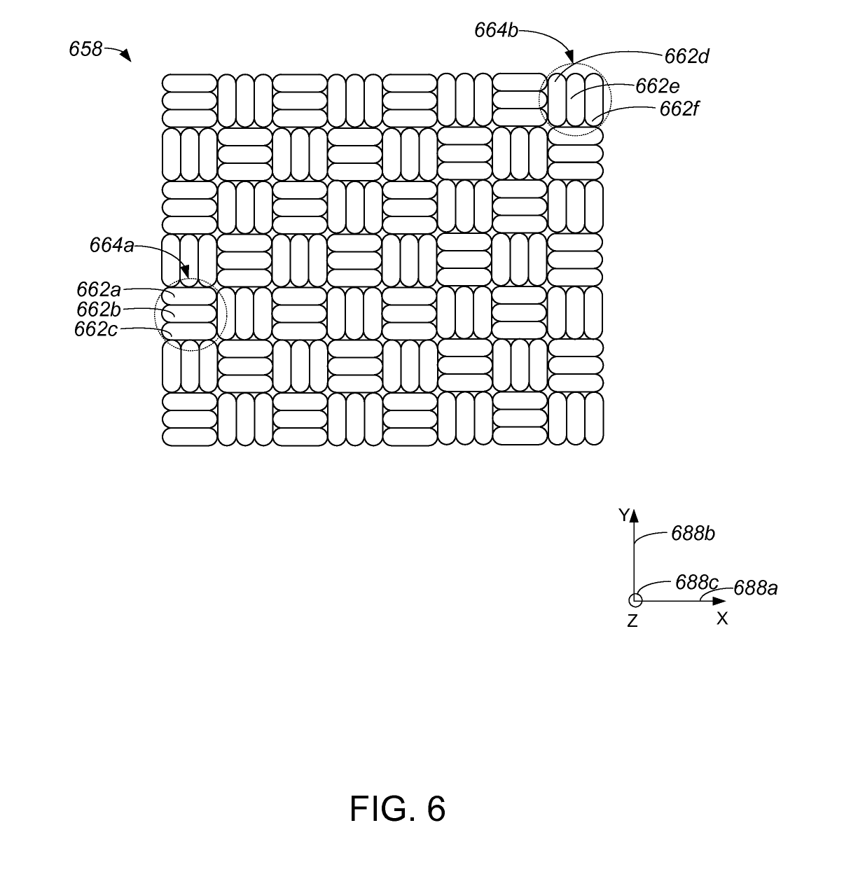

A coil array of a planar motor may often be configured as a checkerboard array of coils. One example of a checkerboard array of coils is shown in FIG. 6. A checkerboard array of coils 658 includes multiple coils 662a-f that are grouped into coil groups 664a, 664b. In the described embodiments, coils 662a-c are included in a first coil group 664a, and coils 662d-f are included in a second coil group 664b. First coil group 664a includes coils 662a-c which are X coils, or coils which are arranged to cooperate with magnets (not shown) to provide force along an x-axis 688a, while second coil group 664b includes coils 662d-f are Y coils which are arranged to cooperate with magnets to provide force along a y-axis 688b.

Array 658 is organized, as shown, in a grid that includes eight columns which include coils 662a-f and coil groups which include coil groups 664a, 664b. As shown, in each column, coil groups that include X coils and coil groups that include Y coils alternate. It should be appreciated that coils and coil groups of array 658 are in substantially the same plane relative to a z-axis 688c.

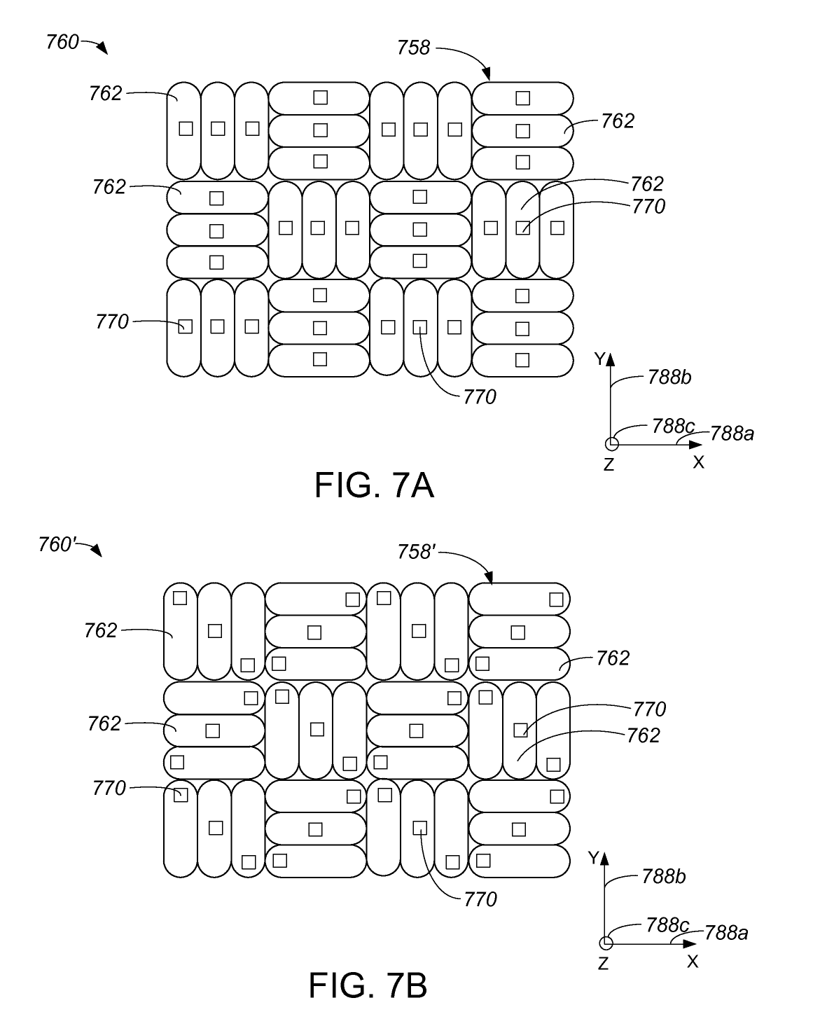

FIGS. 7A and 7B are diagrammatic representations of other suitable Hall sensor configurations in accordance with other embodiments of the present invention. Hall sensor configurations are shown in FIGS. 7A and 7B relative to coils or conductors of a coil array. A coil arrangement 760, which may be part of a planar motor that drives a stage along an z-axis 788a and/or a y-axis 788b, includes a coil array 758′ that includes coils 762, as shown in FIG. 7A. Hall sensors 770 are arranged either under or over coil array 758 relative to a z-axis 788c. Hall sensors 770 of coil arrangement 760 are configured in an approximately 240 degree layout in terms of the phase of motor magnetic flux distribution. Hall sensors 770 of a coil arrangement 760′, as shown in FIG. 7B, are also configured in an approximately 240 degree layout.

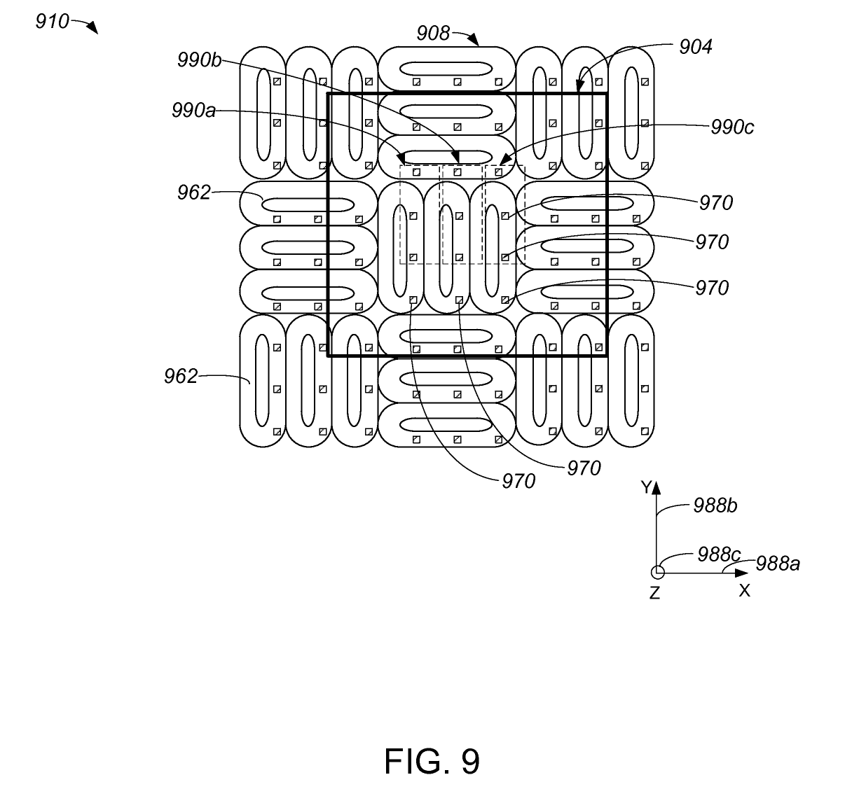

Referring next to FIG. 9, measuring an XZ position of an XZ magnet unit or quadrant using voltages obtained from Hall sensors will be described in accordance with an embodiment of the present invention. FIG. 9 is a diagrammatic representation of a portion of a planar motor in accordance with an embodiment of the present invention. A planar motor 910 that is configured to drive a stage (not shown) includes a coil array 908 and a magnet unit 904 that is part of an overall magnet array. Coil array 908 may be positioned substantially under or substantially over magnet unit 904 relative to a z-axis 988c.

Coil array 908 includes multiple coils 962. In the described embodiment, magnet unit 908 is an XZ magnet unit that is arranged to support movement with respect to an x-axis 988a and a z-axis 988c. Hall sensors 970 are part of a coil arrangement that includes hall sensors 970 and coil array 908. Hall sensors 970 are generally positioned on an opposite side, relative to z-axis 988c, of coil array 908 from magnet unit 904.

In the embodiment as shown, Hall sensors 970 are located under coil array 908 while magnet unit 908 is positioned over coil array 908 with respect to z-axis 988c. After Hall sensors 970 are calibrated, Hall sensors 970 which are located under a central portion of magnet unit 904 may be used to measure x-positions and z-positions of magnet unit 904.

A sensor voltage associated with an area 990a may be expressed as:

$${V}_{u} = A \cdot cos ( θ + \frac{4 π}{3} )$$

A sensor voltage associated with an area 990b may be expressed as:

Vᵥ=A·cos(θ)

A sensor voltage associated with an area 990c may be expressed as:

$${V}_{w} = A \cdot cos ( θ - \frac{4 π}{3} )$$

“θ” is an x-position dependent sensor phase, while “A” is a z-position dependent sensor amplitude. “θ” and “A” may be expressed as follows:

$$θ = \frac{2 π ( x + {x}_{0} )}{{L}_{pitch}}$$

$$A = {a}_{0} + {a}_{1} z + {a}_{2} {z}^{2}$$

The sensor phase “θ” and sensor amplitude “A” may be calculated from the sensor output voltages as follows:

$$θ = {tan}^{- 1} \frac{s}{c}$$

$$A = \sqrt{{s}^{2} + {c}^{2}} where$$

$$s = \frac{1}{\sqrt{3}} ( {V}_{u} - {V}_{w} ) = A \cdot sin θ$$

$$c = - ( {V}_{u} + {V}_{w} ) = A \cdot cos θ$$

From the above-calculated sensor phase “θ” and sensor amplitude “A,” an x position “x” and a z position “z” may be obtained as follows:

$$x = \frac{θ}{2 π} {L}_{pitch} - {x}_{0}$$

$$z = \frac{- {a}_{1} + \sqrt{{a}_{1}^{2} - 4 {a}_{2} ( {a}_{0} - A )}}{2 {a}_{2}}$$

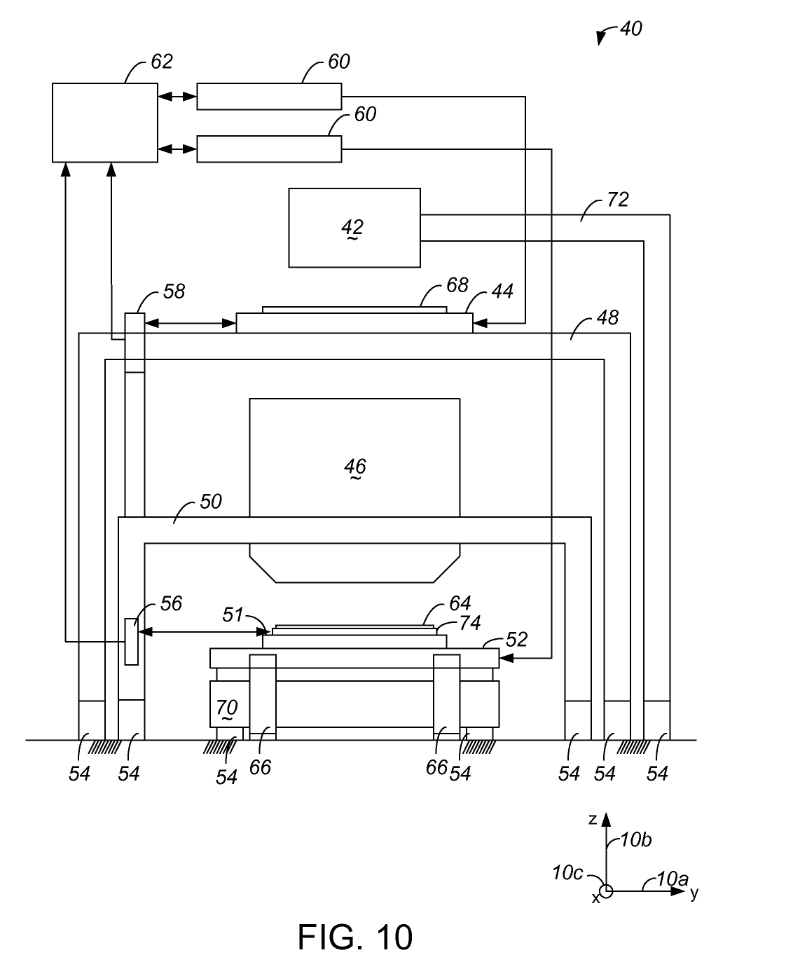

With reference to FIG. 10 a photolithography apparatus which may include a planar stage which uses dynamic correction as discussed above will be described in accordance with an embodiment of the present invention. A photolithography apparatus (exposure apparatus) 40 includes a wafer positioning stage 52 that may be driven by a planar motor (not shown), as well as a wafer table 51 that is magnetically coupled to wafer positioning stage 52 by utilizing an EI-core actuator and/or a voice coil motor. The planar motor which drives wafer positioning stage 52 generally uses an electromagnetic force generated by magnets and corresponding armature coils arranged in two dimensions.

A wafer 64 is held in place on a wafer holder or chuck 74 which is coupled to wafer table 51. Wafer positioning stage 52 is arranged to move in multiple degrees of freedom, e.g., in up to six degrees of freedom, under the control of a control unit 60 and a system controller 62. In one embodiment, wafer positioning stage 52 may include a plurality of actuators and have a configuration as described above. The movement of wafer positioning stage 52 allows wafer 64 to be positioned at a desired position and orientation relative to a projection optical system 46.

Wafer table 51 may be levitated in a z-direction 10b by any number of voice coil motors (not shown), e.g., three voice coil motors. In one described embodiment, at least three magnetic bearings (not shown) couple and move wafer table 51 along a y-axis 10a. The motor array of wafer positioning stage 52 is typically supported by a base 70. Base 70 is supported to a ground via isolators 54. Reaction forces generated by motion of wafer stage 52 may be mechanically released to a ground surface through a frame 66. One suitable frame 66 is described in JP Hei 8-166475 and U.S. Pat. No. 5,528,118, which are each herein incorporated by reference in their entireties.

An illumination system 42 is supported by a frame 72. Frame 72 is supported to the ground via isolators 54. Illumination system 42 includes an illumination source, which may provide a beam of light that may be reflected off of a reticle. In one embodiment, illumination system 42 may be arranged to project a radiant energy, e.g., light, through a mask pattern on a reticle 68 that is supported by and scanned using a reticle stage 44 which may include a coarse stage and a fine stage, or which may be a single, monolithic stage. The radiant energy is focused through projection optical system 46, which is supported on a projection optics frame 50 and may be supported the ground through isolators 54. Suitable isolators 54 include those described in JP Hei 8-330224 and U.S. Pat. No. 5,874,820, which are each incorporated herein by reference in their entireties.

A first interferometer 56 is supported on projection optics frame 50, and functions to detect the position of wafer table 51. Interferometer 56 outputs information on the position of wafer table 51 to system controller 62. In one embodiment, wafer table 51 has a force damper which reduces vibrations associated with wafer table 51 such that interferometer 56 may accurately detect the position of wafer table 51. A second interferometer 58 is supported on projection optical system 46, and detects the position of reticle stage 44 which supports a reticle 68. Interferometer 58 also outputs position information to system controller 62.

It should be appreciated that there are a number of different types of photolithographic apparatuses or devices. For example, photolithography apparatus 40, or an exposure apparatus, may be used as a scanning type photolithography system which exposes the pattern from reticle 68 onto wafer 64 with reticle 68 and wafer 64 moving substantially synchronously. In a scanning type lithographic device, reticle 68 is moved perpendicularly with respect to an optical axis of a lens assembly (projection optical system 46) or illumination system 42 by reticle stage 44. Wafer 64 is moved perpendicularly to the optical axis of projection optical system 46 by a wafer stage 52. Scanning of reticle 68 and wafer 64 generally occurs while reticle 68 and wafer 64 are moving substantially synchronously.

Alternatively, photolithography apparatus or exposure apparatus 40 may be a step-and-repeat type photolithography system that exposes reticle 68 while reticle 68 and wafer 64 are stationary, i.e., at a substantially constant velocity of approximately zero meters per second. In one step and repeat process, wafer 64 is in a substantially constant position relative to reticle 68 and projection optical system 46 during the exposure of an individual field. Subsequently, between consecutive exposure steps, wafer 64 is consecutively moved by wafer positioning stage 52 perpendicularly to the optical axis of projection optical system 46 and reticle 68 for exposure. Following this process, the images on reticle 68 may be sequentially exposed onto the fields of wafer 64 so that the next field of semiconductor wafer 64 is brought into position relative to illumination system 42, reticle 68, and projection optical system 46.

It should be understood that the use of photolithography apparatus or exposure apparatus 40, as described above, is not limited to being used in a photolithography system for semiconductor manufacturing. For example, photolithography apparatus 40 may be used as a part of a liquid crystal display (LCD) photolithography system that exposes an LCD device pattern onto a rectangular glass plate or a photolithography system for manufacturing a thin film magnetic head.

The illumination source of illumination system 42 may be g-line (436 nanometers (nm)), i-line (365 nm), a KrF excimer laser (248 nm), an ArF excimer laser (193 nm), and an F2-type laser (157 nm). Alternatively, illumination system 42 may also use charged particle beams such as x-ray and electron beams. For instance, in the case where an electron beam is used, thermionic emission type lanthanum hexaboride (LaB6) or tantalum (Ta) may be used as an electron gun. Furthermore, in the case where an electron beam is used, the structure may be such that either a mask is used or a pattern may be directly formed on a substrate without the use of a mask.

With respect to projection optical system 46, when far ultra-violet rays such as an excimer laser are used, glass materials such as quartz and fluorite that transmit far ultra-violet rays is preferably used. When either an F2-type laser or an x-ray is used, projection optical system 46 may be either catadioptric or refractive (a reticle may be of a corresponding reflective type), and when an electron beam is used, electron optics may comprise electron lenses and deflectors. As will be appreciated by those skilled in the art, the optical path for the electron beams is generally in a vacuum.

In addition, with an exposure device that employs vacuum ultra-violet (VUV) radiation of a wavelength that is approximately 200 nm or lower, use of a catadioptric type optical system may be considered. Examples of a catadioptric type of optical system include, but are not limited to, those described in Japan Patent Application Disclosure No. 8-171054 published in the Official gazette for Laid-Open Patent Applications and its counterpart U.S. Pat. No. 5,668,672, as well as in Japan Patent Application Disclosure No. 10-20195 and its counterpart U.S. Pat. No. 5,835,275, which are all incorporated herein by reference in their entireties. In these examples, the reflecting optical device may be a catadioptric optical system incorporating a beam splitter and a concave minor. Japan Patent Application Disclosure (Hei) No. 8-334695 published in the Official gazette for Laid-Open Patent Applications and its counterpart U.S. Pat. No. 5,689,377, as well as Japan Patent Application Disclosure No. 10-3039 and its counterpart U.S. Pat. No. 5,892,117, which are all incorporated herein by reference in their entireties. These examples describe a reflecting-refracting type of optical system that incorporates a concave minor, but without a beam splitter, and may also be suitable for use with the present invention.

The present invention may be utilized, in one embodiment, in an immersion type exposure apparatus if suitable measures are taken to accommodate a fluid. For example, PCT patent application WO 99/49504, which is incorporated herein by reference in its entirety, describes an exposure apparatus in which a liquid is supplied to a space between a substrate (wafer) and a projection lens system during an exposure process. Aspects of PCT patent application WO 99/49504 may be used to accommodate fluid relative to the present invention.

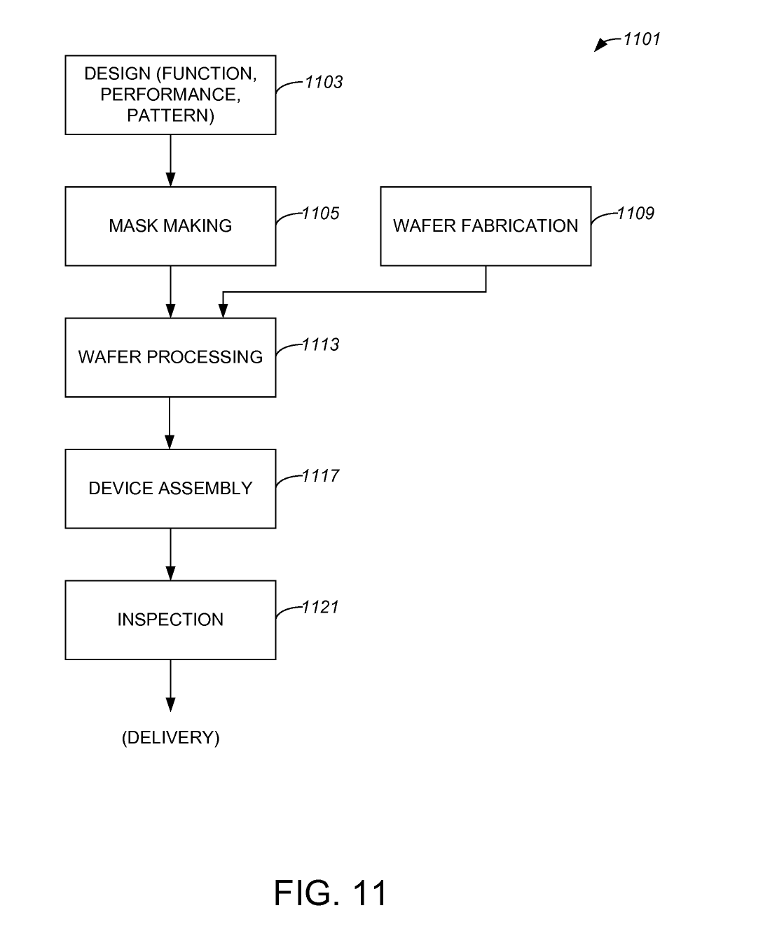

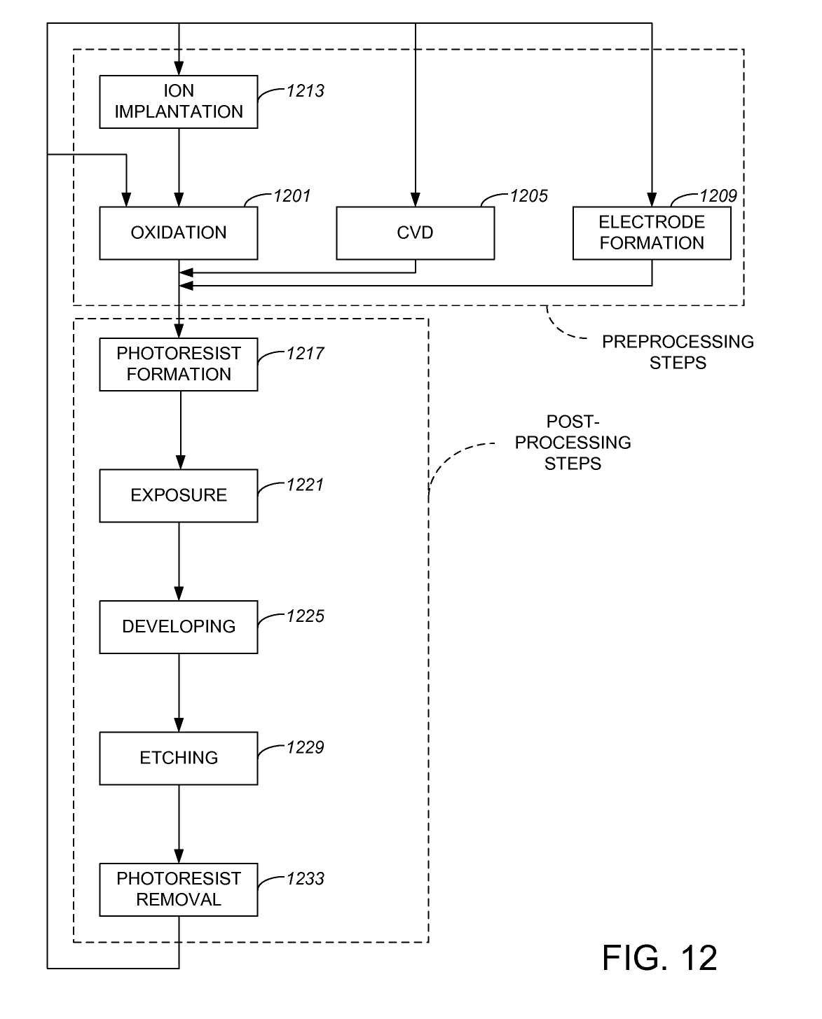

Further, semiconductor devices may be fabricated using systems described above, as will be discussed with reference to FIG. 11. FIG. 11 is a process flow diagram which illustrates the steps associated with fabricating a semiconductor device in accordance with an embodiment of the present invention. A process 1101 of fabricating a semiconductor device begins at step 1103 in which the function and performance characteristics of a semiconductor device are designed or otherwise determined. Next, in step 1105, a reticle or mask in which has a pattern is designed based upon the design of the semiconductor device. It should be appreciated that in a substantially parallel step 1109, a wafer is typically made from a silicon material. In step 1113, the mask pattern designed in step 1105 is exposed onto the wafer fabricated in step 1109. One process of exposing a mask pattern onto a wafer will be described below with respect to FIG. 12. In step 1117, the semiconductor device is assembled. The assembly of the semiconductor device generally includes, but is not limited to including, wafer dicing processes, bonding processes, and packaging processes. Finally, the completed device is inspected in step 1121. Upon successful completion of the inspection in step 1121, the completed device may be considered to be ready for delivery.

FIG. 12 is a process flow diagram which illustrates the steps associated with wafer processing, e.g., step 1113 of FIG. 11, in the case of fabricating semiconductor devices in accordance with an embodiment of the present invention. In step 1201, the surface of a wafer is oxidized. Then, in step 1205 which is a chemical vapor deposition (CVD) step in one embodiment, an insulation film may be formed on the wafer surface. Once the insulation film is formed, then in step 1209, electrodes are formed on the wafer by vapor deposition. Then, ions may be implanted in the wafer using substantially any suitable method in step 1213. As will be appreciated by those skilled in the art, steps 1201-1213 are generally considered to be preprocessing steps for wafers during wafer processing. Further, it should be understood that selections made in each step, e.g., the concentration of various chemicals to use in forming an insulation film in step 1205, may be made based upon processing requirements.

At each stage of wafer processing, when preprocessing steps have been completed, post-processing steps may be implemented. During post-processing, initially, in step 1217, photoresist is applied to a wafer. Then, in step 1221, an exposure device may be used to transfer the circuit pattern of a reticle to a wafer. Transferring the circuit pattern of the reticle of the wafer generally includes scanning a reticle scanning stage.

After the circuit pattern on a reticle is transferred to a wafer, the exposed wafer is developed in step 1225. Once the exposed wafer is developed, parts other than residual photoresist, e.g., the exposed material surface, may be removed by etching in step 1229. Finally, in step 1233, any unnecessary photoresist that remains after etching may be removed. As will be appreciated by those skilled in the art, multiple circuit patterns may be formed through the repetition of the preprocessing and post-processing steps.

Although only a few embodiments of the present invention have been described, it should be understood that the present invention may be embodied in many other specific forms without departing from the spirit or the scope of the present invention. By way of example, while the use of Hall sensors such as Hall Effect sensors has been described, it should be appreciated that Hall sensors may also include Hall Effect probes. Further, it should be appreciated that Hall sensors are an example of suitable magnetic sensors for use in measuring stage positions.

The many features of the embodiments of the present invention are apparent from the written description. Further, since numerous modifications and changes will readily occur to those skilled in the art, the present invention should not be limited to the exact construction and operation as illustrated and described. Hence, all suitable modifications and equivalents may be resorted to as falling within the spirit or the scope of the present invention.

What is claimed is:

1. An apparatus, comprising:
a stage;
at least a first coil, the at least first coil being included in a coil array, the coil array being a part of a coil arrangement;
at least a first magnet, the first magnet being configured to cooperate with the first coil to form a motor arranged to drive the stage;
a dynamics model arrangement, the dynamics model arrangement being configured to obtain a coil current command provided to the at least first coil and to provide a first signal based on the coil current command;
at least a first plurality of magnetic sensors, the first plurality of magnetic sensors being included in the coil arrangement, the first plurality of magnetic sensors being configured to measure a flux, wherein the flux includes a magnetic component associated with the at least first magnet and a coil component associated with the at least first coil; and
a stage position estimation module, the stage position estimation module being configured to obtain the flux and the first signal, the stage position estimation module further being configured to process the flux and the first signal to estimate a position of the stage.

2. The apparatus of claim 1 wherein the coil array is positioned between the first plurality of magnetic sensors and the at least first magnet relative to a z-axis, and wherein the first plurality of magnetic sensors is mounted to the coil array.

3. The apparatus of claim 1 wherein the coil array is positioned over the at least first magnet relative to a z-axis, and wherein the first plurality of magnetic sensors is located at a distance from the coil array such that the coil array is positioned between the at least first magnet and the first plurality of magnetic sensors relative to the z-axis.

4. The apparatus of claim 1 wherein the first signal is an estimate of a coil flux generated by the at least first coil.

5. The apparatus of claim 4 wherein the dynamics model arrangement includes an amplifier dynamics model and a magnetic sensor dynamics model.

6. The apparatus of claim 5 wherein the amplifier dynamics model is configured to process the coil current command to obtain a second signal, the second signal including a coil flux interference DC gain, and wherein the magnetic sensor dynamics model is configured to process the second signal to obtain the first signal.

7. The apparatus of claim 6 wherein the stage position estimation module is configured to utilize a difference between the flux and the first signal to estimate the position of the stage.

8. The apparatus of claim 1 wherein the apparatus is an exposure apparatus.

9. A wafer formed using the exposure apparatus of claim 8.

10. The apparatus of claim 1 wherein the first plurality of magnetic sensors is a first plurality of Hall sensors.

11. An apparatus, comprising:
a stage;
a first coil, the first coil being included in a coil array, the coil array being a part of a coil arrangement;
a second coil, the second coil being included in the coil array;
at least a first magnet, the first magnet being configured to cooperate with the coil array to form a planar motor arranged to drive the stage;
a first dynamics model arrangement, the first dynamics model arrangement being configured to obtain a first coil current command provided to the first coil and to provide a first signal based on the first coil current command;
a second dynamics model arrangement, the second dynamics model arrangement being configured to obtain a second coil current command provided to the second coil and to provide a second signal based on the second coil current command; and
a first magnetic sensor, the first magnetic sensor being included in the coil arrangement, the first magnetic sensor being configured to measure a flux, wherein the flux includes a magnetic component associated with the at least first magnet and a first coil component associated with the at first coil and a second coil component associated with the second coil, wherein a calibrated magnetic sensor signal is obtained by compensating for the first coil component and the second coil component in the flux.

12. The apparatus of claim 11 further including:
a stage position estimation module, the stage position estimation module being configured to obtain the calibrated magnetic sensor signal, the stage position estimation module further being configured to process the calibrated magnetic sensor signal to estimate a position of the stage.

13. The apparatus of claim 11 wherein the coil array is positioned between the first magnetic sensor and the at least first magnet relative to a z-axis, and wherein the first magnetic sensor is mounted to the coil array.

14. The apparatus of claim 11 wherein the coil array is positioned over the at least first magnet relative to a z-axis, and wherein the first magnetic sensor is located at a distance from the coil array such that the coil array is positioned between the at least first magnet and the magnetic sensor relative to the z-axis.

15. The apparatus of claim 11 wherein the first signal includes a first coil flux interference DC gain and the second signal includes a second coil flux interference DC gain.

16. The apparatus of claim 11 wherein the first coil component is a first magnetic flux associated with the first coil, the first coil being energized.

17. The apparatus of claim 16 wherein the second coil component is a second magnetic flux associated with the second coil, the second magnetic flux being generated by an influence of mutual induction from the first coil.

18. The apparatus of claim 11 wherein the apparatus is an exposure apparatus.

19. A wafer formed using the exposure apparatus of claim 18.

20. The apparatus of claim 11 wherein the first magnetic sensor is a first Hall sensor.
